(19) United States
(12) Patent Application Publication
(10) Pub. No.: US 2026/0293144 A1
(43) Pub. Date: Sep. 24, 2026

(54) SEMICONDUCTOR STORAGE DEVICE AND METHOD FOR MANUFACTURING SEMICONDUCTOR STORAGE DEVICE

(71) Applicant: Kioxia Corporation, Tokyo (JP)

(72) Inventor: Hiroaki KOBAYASHI, Yokkaichi (JP)

(73) Assignee: Kioxia Corporation, Tokyo (JP)

(21) Appl. No.: 19/325,589

(22) Filed: Sep. 11, 2025

(30) Foreign Application Priority Data
Mar. 18, 2025 (JP) 2025-043045

(51) Int. Cl. H10B 43/50; H01L 23/544; H10B 41/10; H10B 41/20; H10B 41/50; H10B 43/10; H10B 43/20

(52) U.S. Cl. CPC H10B 43/50; H10B 41/10; H10B 41/20; H10B 41/50; H10B 43/10; H10B 43/20; H10W 46/00; H10W 46/301

(57) ABSTRACT

A semiconductor storage device includes: a device region; and a mark region. First and second stacked bodies are in the device and mark regions. First patterns are in the first stacked body in the device region. Second patterns, each having a dimension identical to that of one first pattern and extending in the stack direction is in the first stacked body in the mark region. A region in which the second patterns are formed includes first and second regions. A second pattern inside of which is filled among the second patterns is in the first region. A second pattern inside which a cavity is formed is in the second region. A step region is in a portion of the second stacked body in the mark region, the portion being overlaid on the second region. The step region is lower than a surface of a portion overlaid on the first region.

### CROSS-REFERENCE TO RELATED APPLICATION

This application is based upon and claims the benefit of priority from Japanese Patent Application No. 2025-043045, filed Mar. 18, 2025, the entire contents of which are incorporated herein by reference.

### FIELD

Embodiments described herein relate generally to a semiconductor storage device and a method for manufacturing the semiconductor storage device.

### BACKGROUND

In a semiconductor storage device such as a three-dimensional non-volatile memory, pillars extending in a stacked body in which a plurality of electrically conductive layers and a plurality of insulating layers are alternately stacked are disposed. Memory cells are formed at the intersections between the pillars and the plurality of electrically conductive layers.

In the semiconductor storage device, more layers tend to be stacked in the stacked body as storage capacity increases. To increase layers to be stacked in number, the stacked body is divided into a plurality of hierarchical layers and the stacked body is gradually formed in some cases. In a case where the stacked body is gradually formed, the overlay accuracy between the respective hierarchical layers is required.

### BRIEF DESCRIPTION OF THE DRAWINGS

FIG. 1 is a diagram schematically illustrating a configuration example of a semiconductor storage device according to an embodiment.

FIG. 2 is a cross-sectional view of a configuration example of a part of a device region according to the embodiment.

FIG. 3 is a diagram illustrating a configuration example of a part of a mark region according to the embodiment.

FIG. 4 is a flowchart illustrating an example of a procedure of a method for manufacturing the semiconductor storage device according to the embodiment.

FIG. 5 is a schematic cross-sectional view of an example of a procedure of a method for manufacturing the semiconductor storage device in the device region according to the embodiment.

FIG. 6 is a schematic cross-sectional view of the example of the procedure of the method for manufacturing the semiconductor storage device in the device region according to the embodiment.

FIG. 7 is a schematic cross-sectional view of an example of a procedure of a method for manufacturing the semiconductor storage device in the mark region according to the embodiment.

FIG. 8 is a schematic cross-sectional view of the example of the procedure of the method for manufacturing the semiconductor storage device in the mark region according to the embodiment.

FIG. 9 is a schematic cross-sectional view of the example of the procedure of the method for manufacturing the semiconductor storage device in the mark region according to the embodiment.

FIG. 10 is a schematic cross-sectional view of the example of the procedure of the method for manufacturing the semiconductor storage device in the mark region according to the embodiment.

FIG. 11 is a schematic cross-sectional view of the example of the procedure of the method for manufacturing the semiconductor storage device in the mark region according to the embodiment.

FIG. 12 is a schematic cross-sectional view of the example of the procedure of the method for manufacturing the semiconductor storage device in the mark region according to the embodiment.

### DETAILED DESCRIPTION

One or more embodiments may provide a semiconductor storage device having high overlay accuracy and a method for manufacturing the semiconductor storage device.

In general, according to one embodiment, a semiconductor storage device includes: a device region in which a plurality of memory cells is formed; and a mark region provided around the device region. A first stacked body in which a plurality of first electrically conductive layers is stacked to be spaced apart from each other and a second stacked body in which a plurality of second electrically conductive layers is stacked to be spaced apart from each other are formed in the device region and the mark region. The second stacked body is disposed above the first stacked body. A plurality of first patterns each extending in a stack direction of the first stacked body is formed in the first stacked body in the device region. The plurality of first patterns constitutes the plurality of memory cells. A plurality of second patterns each having a dimension identical to a dimension of one of the plurality of first patterns and extending in the stack direction is formed in the first stacked body in the mark region. A region in which the plurality of second patterns is formed is provided with a first region and a second region surrounded by the first region. A second pattern inside of which is filled among the plurality of second patterns is disposed in the first region. A second pattern inside which a cavity is formed among the plurality of second patterns is disposed in the second region. A step region is formed in a portion of the second stacked body in the mark region, the portion being overlaid on the second region. The step region is lower than a surface of a portion overlaid on the first region.

Hereinafter, an embodiment will be described in detail with reference to the drawings. It is to be noted that the present invention is not limited by the following embodiment. In addition, components in the following embodiment include components that those skilled in the art could have easily conceived or substantially the same components.

In the present specification, the directions along the direction of surfaces of electrically conductive layers WL1 and WL2 described below are defined as an X direction and a Y direction. The X direction and the Y direction are orthogonal to each other. In addition, the direction orthogonal to the X direction and the Y direction is defined as a Z direction. The Z direction is also the stack direction of the electrically conductive layers WL1 and WL2. In addition, the direction indicated by the arrow of each of the axes is defined as a positive direction and the opposite direction is defined as a negative direction. The positive direction of Z is defined as an up direction and the negative direction of Z is defined as a down direction.

### Configuration of Semiconductor Storage Device

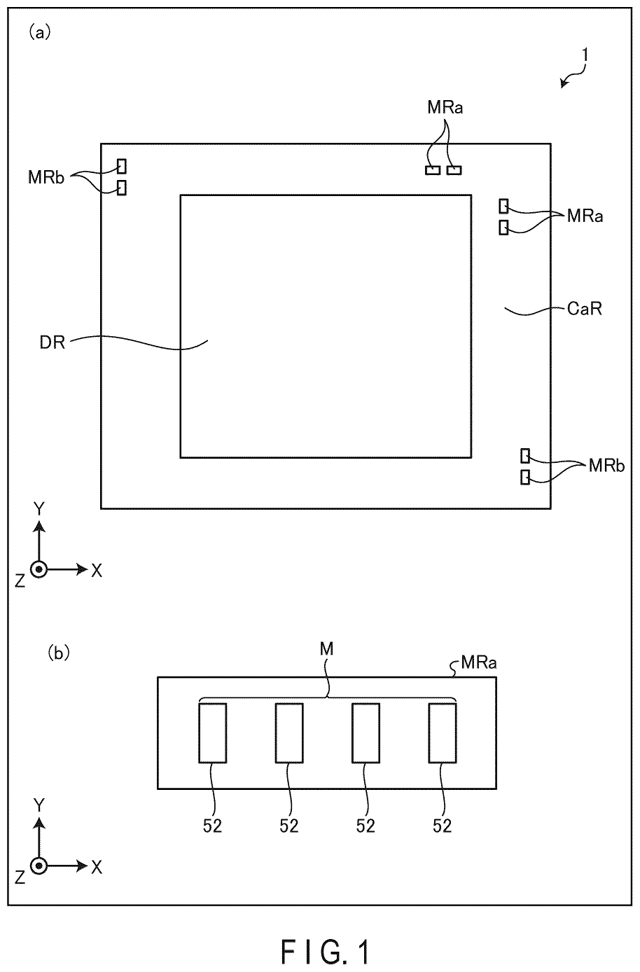

FIG. 1 is a diagram schematically illustrating a configuration example of a semiconductor storage device 1 according to an embodiment. If described in more detail, the part (a) of FIG. 1 is a top view of the semiconductor storage device 1. The part (b) of FIG. 1 is an enlarged view of one of mark regions MRa in the part (a) of FIG. 1.

As illustrated in the part (a) of FIG. 1, the semiconductor storage device 1 includes a device region DR and a kerf region CaR.

The device region DR is a region in which a device pattern is formed. The device pattern is obtained by processing stacked bodies in which a plurality of layers is stacked. A plurality of memory cells is formed in the plurality of respective layers. That is, the semiconductor storage device 1 is configured as a three-dimensional non-volatile memory in which a plurality of memory cells is three-dimensionally disposed.

The kerf region CaR is a region provided to surround the device region DR. The kerf region CaR is provided with the mark regions MRa and MRb. Alignment marks and overlay measurement marks to be used for an alignment process for forming the device pattern are disposed in the respective mark regions MRa and MRb.

For example, alignment marks are formed in the mark regions MRa. The alignment marks are each used to adjust the overlay position of exposure light at the time of processing the stacked bodies in the device region DR. In addition, overlay measurement marks are formed in the mark regions MRb. The overlay measurement marks are each used to measure an overlay error after exposure.

As the alignment process, the overlay position of exposure light is, for example, adjusted using an alignment mark and an overlay error is measured using an overlay measurement mark. This offers predetermined overlay accuracy. It is to be noted that the alignment marks and the overlay measurement marks will be referred to as marks M below in the present specification in some cases.

As illustrated in the part (b) of FIG. 1, the marks M each include a plurality of step regions 52 arranged in parallel. Although described in detail below, each of the step regions 52 is a region in which a part of a surface of the mark region MR is lowered in the negative direction of Z.

As viewed from the positive direction of Z, the individual step regions 52 are each formed to have a substantially rectangular shape. The individual step regions 52 are disposed side by side along the X direction that is a transverse direction. The individual step regions 52 each have, for example, a width of 1 μm in the transverse direction. That is, the individual step regions 52 each allow for image formation using visible light. At the time of the alignment process, the marks M including the plurality of step regions 52 like these are observed using an optical microscope or the like.

It is to be noted that the mark M illustrated in the part (b) of FIG. 1 is merely an example, e.g., various patterns may be used as the mark M.

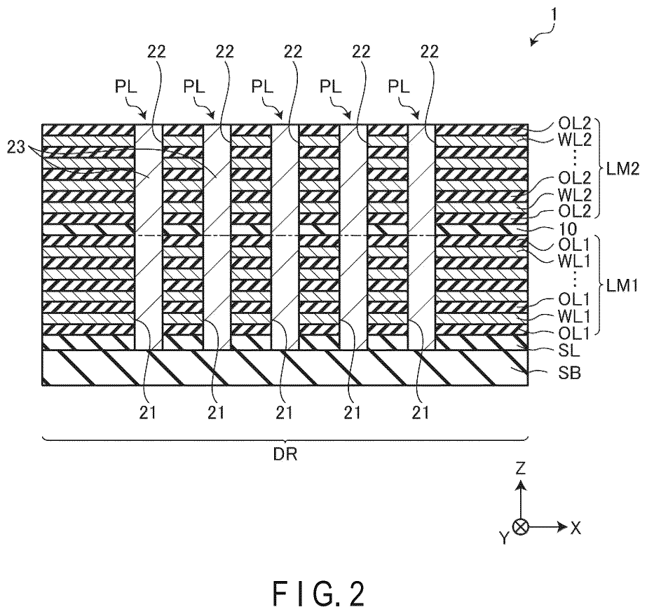

FIG. 2 is a cross-sectional view of a configuration example of a part of the device region DR according to the embodiment.

As illustrated in FIG. 2, a source line SL, a stacked body LM1, and a stacked body LM2 are formed in this order on a substrate SB in the device region DR of the semiconductor storage device 1. The stacked body LM1 has a configuration in which the plurality of electrically conductive layers WL1 is stacked to be spaced apart from each other with a plurality of insulating layers OL1 in between and the stacked body LM2 has a configuration in which the plurality of electrically conductive layers WL2 is stacked to be spaced apart from each other with a plurality of insulating layers OL2 in between. The stacked body LM1 is an example of a first stacked body and the stacked body LM2 is an example of a second stacked body.

The electrically conductive layers WL1 and WL2 are, for example, tungsten layers or the like. The insulating layers OL1 and OL2 are, for example, silicon oxide layers. The stacked body LM1 and the stacked body LM2 each do not transmit visible light. The electrically conductive layer WL1 is an example of a first electrically conductive layer and the electrically conductive layer WL2 is an example of a second electrically conductive layer.

An insulating layer 10 is formed between the uppermost insulating layer OL1 of the stacked body LM1 and the lowermost insulating layer OL2 of the stacked body LM2. The insulating layer 10 is, for example, a silicon oxide layer or the like. The insulating layer 10, the uppermost insulating layer OL1 of the stacked body LM1, and the lowermost insulating layer OL2 of the stacked body LM2 are thus substantially integrated.

A plurality of memory pillars PL is formed in the stacked body LM1, the insulating layer 10, and the stacked body LM2. The plurality of memory pillars PL extends through the stacked body LM1, the insulating layer 10, and the stacked body LM2 in the Z direction. The individual memory pillars PL each have a configuration in which a pillar layer 23 is disposed inside a memory hole 21 and a memory hole 22 that are connected in the Z direction.

The memory hole 21 is a substantially columnar hole pattern that extends through the stacked body LM1 in the Z direction and terminates in the source line SL. In addition, the memory hole 22 is a substantially columnar hole pattern that extends through the stacked body LM2 and the insulating layer 10 in the Z direction and connects to the upper end of the memory hole 21. The dimensions of the memory holes 21 and 22 in the XY directions are, for example, 100 nm or less and the pitches of the memory holes 21 and 22 in the XY directions are, for example, 200 nm or less. That is, the dimensions and the pitches of the memory holes 21 and 22 in the XY directions are less than or equal to the wavelength of visible light. The memory hole 21 is an example of a first pattern.

For example, a core insulating layer, semiconductor channel layer, memory layer, and the like are concentrically formed as the pillar layer 23 inside the memory hole 21 and the memory hole 22 connected in the Z direction. Memory cells are formed at the opposed portions between the plurality of electrically conductive layers WL1 and the memory layer and the opposed portions between the plurality of electrically conductive layers WL2 and the memory layer. That is, the memory hole 21 and the memory hole 22 each include the pillar layer 23 inside, thereby constituting a plurality of memory cells.

The memory hole 21 and the memory hole 22 are gradually formed. Specifically, first of all, the memory holes 21 are formed and the memory holes 22 are formed in accordance with the positions of the upper ends of the formed memory holes 21. When the memory holes 22 are formed, an alignment process is performed using the marks M (see the part (b) of FIG. 1).

It is to be noted that FIG. 2 illustrates an appropriate number of electrically conductive layers WL1 and WL2 and an appropriate number of insulating layers OL1 and OL2 for description, or the number of electrically conductive layers WL1 and WL2 may vary and may be determined as appropriate. For example, 48 electrically conductive layers or 64 or 96 electrically conductive layers may be formed.

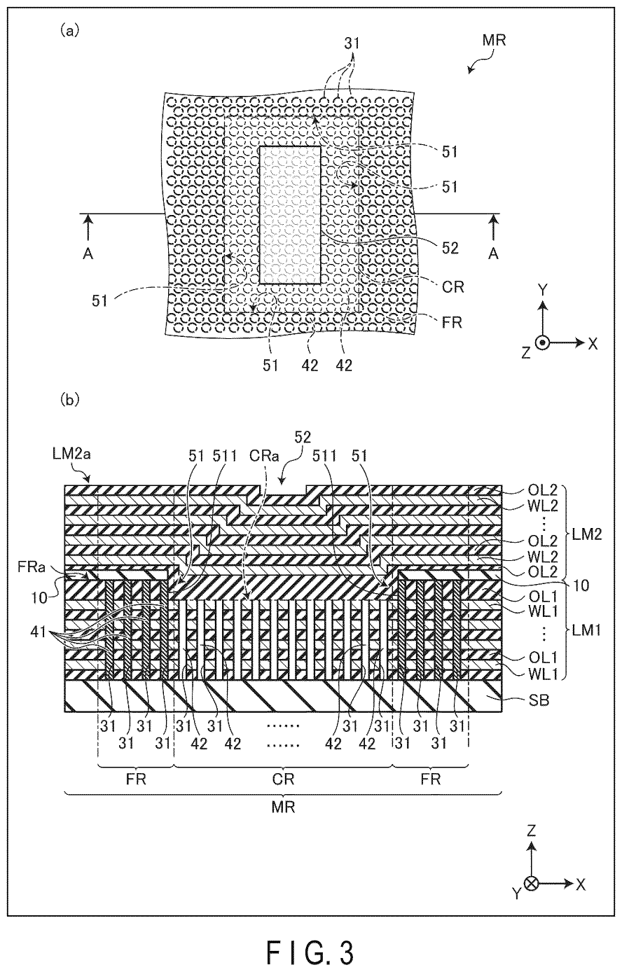

FIG. 3 is a diagram illustrating a configuration example of a part of the mark region MR according to the embodiment. If described in more detail, the part (a) of FIG. 3 is a top view of the surroundings of the step region 52 of one of the marks M (see the part (b) of FIG. 1) formed in the mark region MR. The part (b) of FIG. 3 is a cross-sectional view taken along a line AA in the part (a) of FIG. 3.

As illustrated in the parts (a) and (b) of FIG. 3, the stacked body LM1 and the stacked body LM2 are formed in this order on the substrate SB in the mark region MR. The insulating layer 10 is formed between the stacked body LM1 and the stacked body LM2.

A plurality of memory holes 31 extending through the stacked body LM1 in the Z direction is formed in the stacked body LM1. The plurality of memory holes 31 is hole patterns configured to have substantially columnar shapes with the same dimensions and pitches in the XY directions as those of the plurality of memory holes 21 (see FIG. 2) formed in the device region DR. In other words, the plurality of memory holes 31 is patterns that are exposed and processed at the same time as the plurality of memory holes 21 when the plurality of memory holes 21 is formed. The plurality of memory holes 31 is formed in a matrix in each of the mark regions MR. The memory hole 31 is an example of a second pattern.

The region in which the plurality of memory holes 31 is formed is provided with or in a filler region FR and a substantially rectangular cavity region CR surrounded by the filler region FR.

The cavity region CR is a region provided closer to the inner side of the mark region MR. The cavity region CR is a region formed to have a substantially rectangular shape as viewed from the Z direction. Cavities 42 are formed inside the plurality of memory holes 31 disposed in the cavity region CR, e.g., the plurality of memory holes 31 in the cavity region CR are unfilled. That is, the cavity region CR is a region in which the plurality of memory holes 31 inside which the cavities 42 are formed is disposed. The cavity region CR is an example of a second region.

The filler region FR is a frame-shaped region surrounding the cavity region CR as viewed from the Z direction. The inside of each of the plurality of memory holes 31 disposed in the filler region FR is filled with a sacrificial layer 41. That is, the filler region FR is a region in which the plurality of memory holes 31 the inside of each of which is filled with the sacrificial layer 41 is disposed. The sacrificial layer 41 is, for example, a layer containing carbon such as amorphous carbon. The filler region FR is an example of a first region.

A step 51 down from an upper surface FRa of the filler region FR to an upper surface CRa of the cavity region CR is formed at the border portion between the filler region FR and the cavity region CR. A part of the memory hole 31 disposed in the filler region FR is exposed on a side surface 511 of the step 51 facing the cavity region CR.

As illustrated in the part (b) of FIG. 3, the insulating layer 10 and the respective layers of the stacked body LM2 are stacked on the respective portions of the side surface 511, the upper surface FRa of the filler region FR, and the upper surface CRa of the cavity region CR like these to each have a predetermined thickness. This sequentially transfers the shapes of the memory holes 31 exposed on the side surface 511 of the step 51 to the insulating layer 10 and the respective layers of the stacked body LM2 to form the step region 52 on an upper surface LM2a of the stacked body LM2.

The thicknesses of the insulating layer 10 and the respective layers of the stacked body LM2 are defined in advance. The position of the step region 52 is therefore determined based on information regarding the thicknesses of the insulating layer 10 and the respective layers of the stacked body LM2 and positional information about the memory holes 31 exposed on the side surface 511 of the step 51. That is, the step region 52 is formed to include the positional information about the memory holes 31 exposed on the side surface 511 of the step 51.

The step region 52 is formed on the portion of the upper surface LM2a of the stacked body LM2 overlaid on the cavity region CR. In addition, the step region 52 is formed to be lower in the negative direction of Z than the portion of the upper surface LM2a of the stacked body LM2 overlaid on the filler region FR.

As described above, when the memory holes 22 are formed in the device region DR (see FIG. 2), an alignment process is performed using the step region 52 (mark M) as described above. This makes it possible to perform an alignment process on the memory holes 21 formed in the stacked body LM1 even in a case where the stacked body LM2 does not transmit visible light.

In addition, the area of the step region 52 is smaller than the area of the cavity region CR. In other words, the area of the cavity region CR is larger than the area of the step region 52. In the example in the part (b) of FIG. 3, while the cavity region CR has a width of about 3 μm in the X direction, the step region 52 has a width of about 1 μm in the X direction.

### Method for Manufacturing Semiconductor Storage Device 1

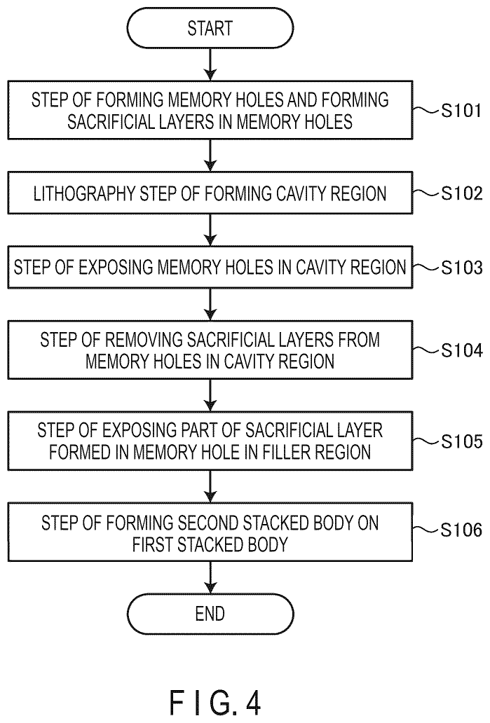

Hereinafter, a method for forming the respective components in the mark region MR and the device region DR according to the embodiment will be described with reference to FIGS. 4 to 12.

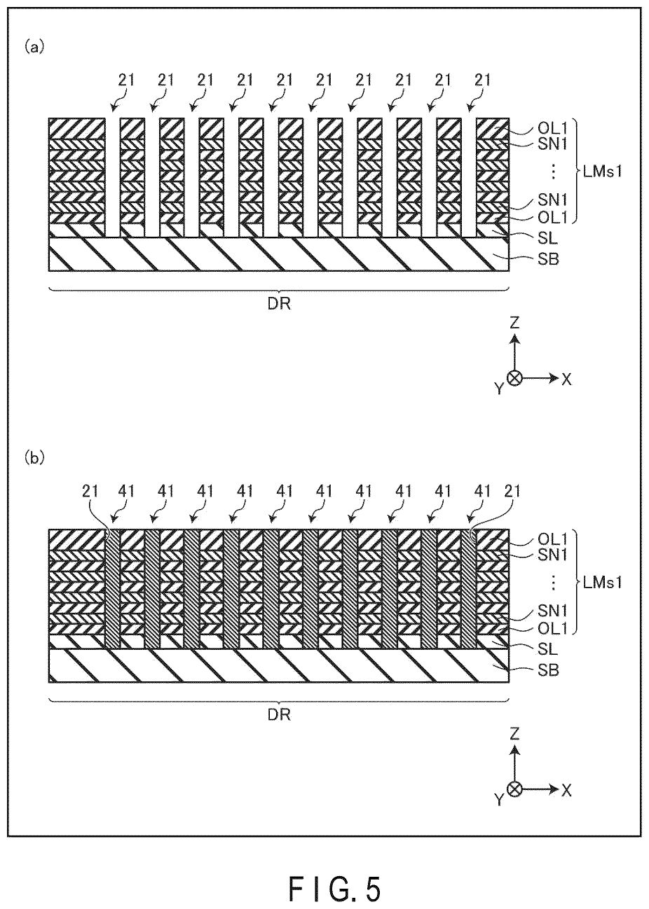

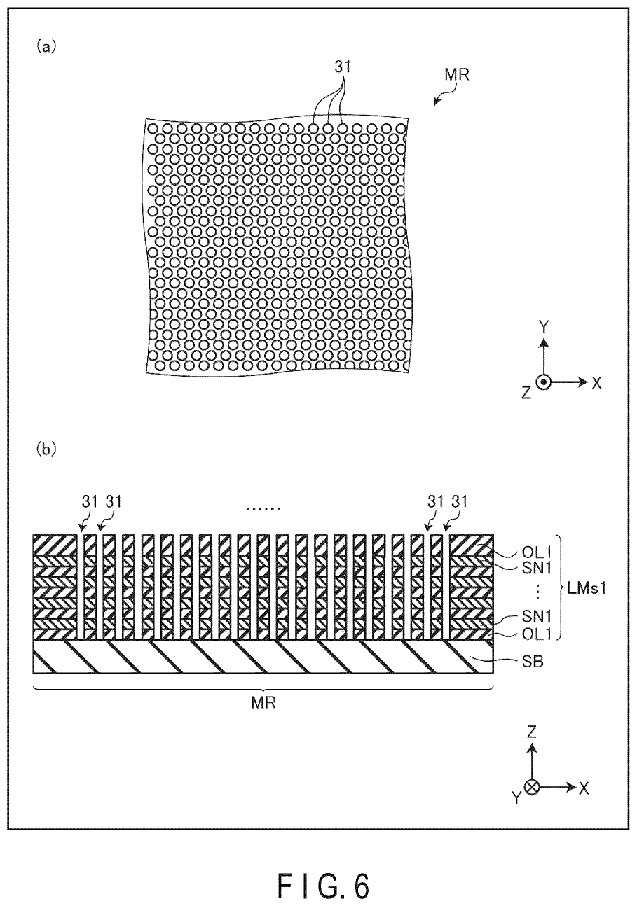

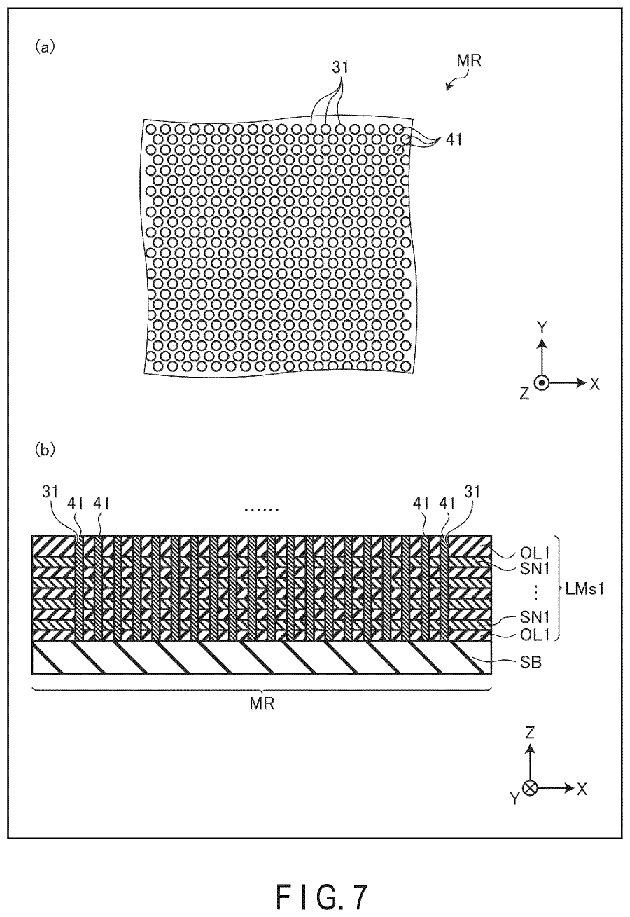

FIG. 4 is a flowchart illustrating an example of a procedure of a method for manufacturing the semiconductor storage device 1 according to the embodiment. FIGS. 5 to 6 are schematic cross-sectional views of an example of a procedure of a method for manufacturing the semiconductor storage device 1 in the device region DR according to the embodiment. If described in more detail, FIGS. 5 to 6 are diagrams corresponding to FIG. 2. FIGS. 7 to 12 are schematic cross-sectional views of an example of a procedure of a method for manufacturing the semiconductor storage device 1 in the mark region MR according to the embodiment. FIGS. 7 to 12 are diagrams corresponding to the part (b) of FIG. 3.

First, a process of forming the memory holes 21 in the device region DR and forming the memory holes 31 in the mark region MR, and forming the sacrificial layers 41 in the formed memory holes 21 and 31 is performed (S101 in FIG. 4).

Specifically, as illustrated in the part (a) of FIG. 5, the source line SL and a stacked body LMs1 are formed in this order on the substrate SB in the device region DR. The stacked body LMs1 is formed by alternately stacking the plurality of insulating layers OL1 and a plurality of sacrificial layers SN1 one by one. The sacrificial layers SN1 are, for example, silicon nitride layers. The sacrificial layers SN1 are layers that are each replaced with a metal layer to serve as the electrically conductive layer WL1 in a subsequent process. It is to be noted that the stacked body LMs1 is also formed in the mark region MR. The stacked body LMs1 is an example of the first stacked body.

Subsequently, the plurality of memory holes 21 each extending through the stacked body LMs1 in the Z direction and having a lower end reaching the source line SL is formed in the device region DR. The memory hole 21 is an example of the first pattern.

At the same time as the formation of the plurality of memory holes 21, the plurality of memory holes 31 extending through the stacked body LMs1 in the Z direction is formed in the mark region MR as illustrated in the parts (a) and (b) of FIG. 6. The plurality of memory holes 31 has the same dimensions and pitches as the dimensions and the pitches of the plurality of memory holes 21 in the XY directions. The memory hole 31 is an example of the second pattern.

Subsequently, as illustrated in the part (b) of FIG. 5 and the parts (a) and (b) of FIG. 7, the sacrificial layers 41 are disposed inside the respective formed memory holes 21 and the respective formed memory holes 31. The sacrificial layers 41 are layers each containing carbon. The sacrificial layers 41 may be thus removed by ashing or the like.

Subsequently, a lithography process for forming the cavity region CR in the region in which the plurality of memory holes 31 filled with the sacrificial layers 41 is formed is performed in the mark region MR (S102 in FIG. 4).

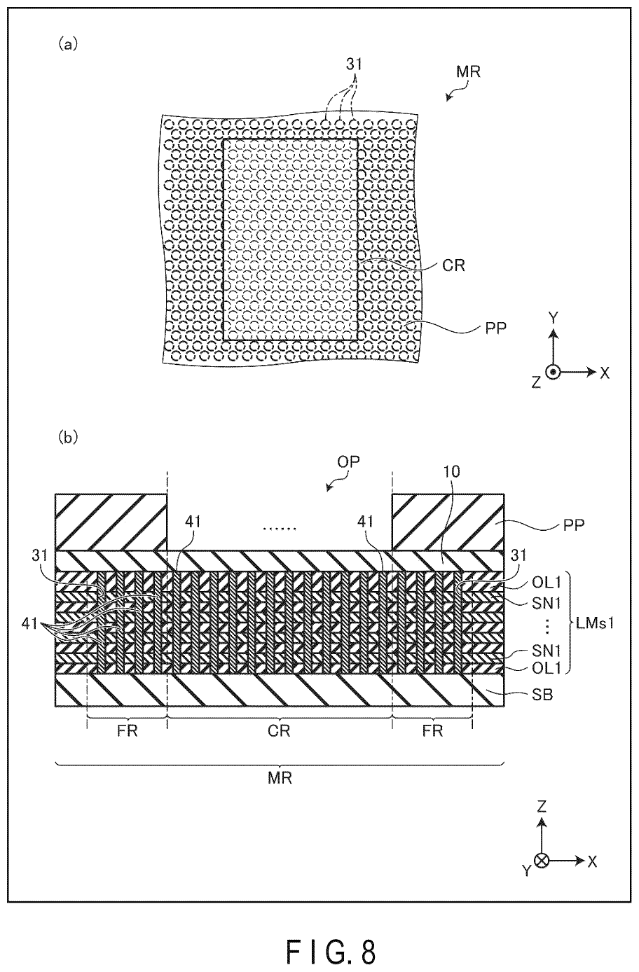

Specifically, first, the insulating layer 10 is further stacked on the uppermost insulating layer OL1 of the stacked body LMs1 as illustrated in the parts (a) and (b) of FIG. 8. This covers the upper surfaces of the plurality of memory holes 31 with the insulating layer 10.

Subsequently, a resist pattern PP that covers the filler region FR and has an opening of the cavity region CR is formed on the insulating layer 10. The insulating layer 10 is exposed in an opening OP of the resist pattern PP. The resist pattern PP is an example of a mask pattern. The filler region FR is an example of the first region. The cavity region CR is an example of the second region.

Subsequently, a process of exposing the memory holes 31 disposed in the cavity region CR is performed (S103 in FIG. 4).

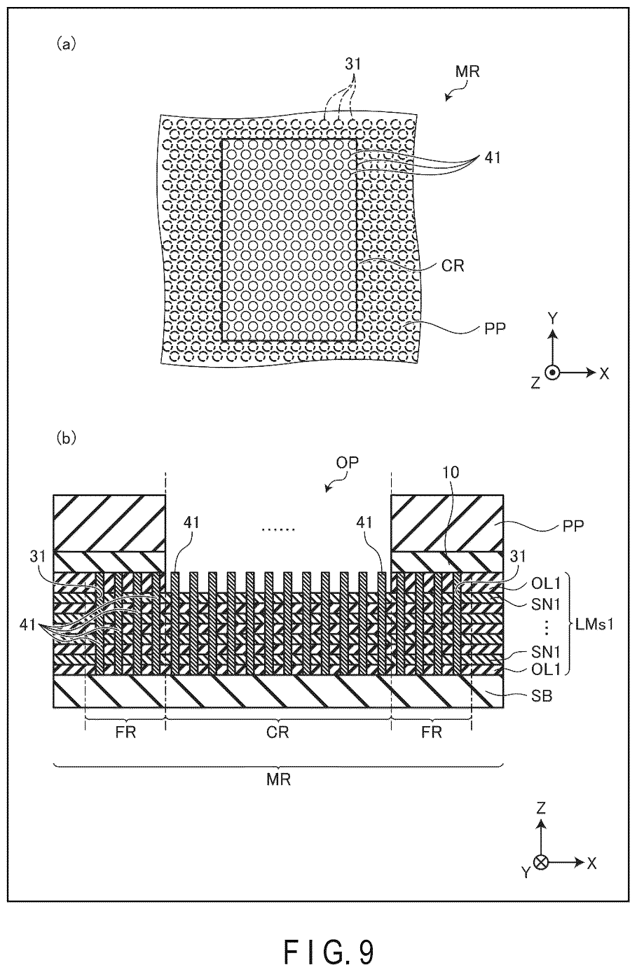

Specifically, as illustrated in the parts (a) and (b) of FIG. 9, the insulating layer 10 exposed in the opening OP by performing an etching process or the like using the resist pattern PP as a mask and the insulating layer OL1 (the uppermost insulating layer OL1 of the stacked body LMs1) located immediately below the insulating layer 10 are removed. This exposes the uppermost sacrificial layer SN1 of the stacked body LMs1, the memory holes 31 disposed in the cavity region CR, and the upper ends of the sacrificial layers 41 projecting from the memory holes 31 in the opening OP.

Subsequently, a process of removing the sacrificial layers 41 from the memory holes 31 exposed in the opening OP is performed (S104 in FIG. 4).

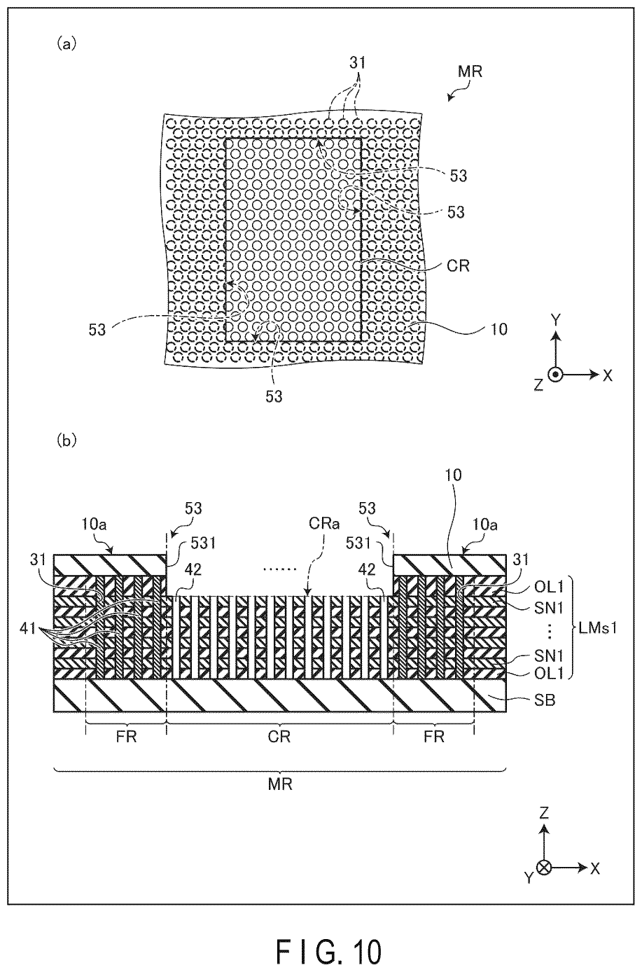

Specifically, as illustrated in FIG. 10, the sacrificial layers 41 are removed from the memory holes 31 exposed in the opening OP using an ashing device. This forms the cavities 42 inside the memory holes 31 in the cavity region CR. In addition, the resist pattern PP formed on the insulating layer 10 is also removed along with the removal of the sacrificial layers 41.

A step 53 down from an upper surface 10a of the insulating layer 10 to the upper surface CRa of the cavity region CR is thus formed at the border portion between the filler region FR and the cavity region CR. At this time, the memory hole 31 disposed in the filler region FR is not exposed on a side surface 531 of the step 53 facing the cavity region CR. The upper surfaces of the memory holes 31 disposed in the filler region FR are covered with the insulating layer 10 and the side surfaces of the memory holes 31 are covered with the stacked body LMs1. The cavities 42 are not therefore formed in the memory holes 31 disposed in the filler region FR. The step 53 is an example of a first step.

Subsequently, a process of exposing a part of each of the sacrificial layers 41 with which the inside of the memory holes 31 in the filler region FR is filled is performed (S105 in FIG. 4).

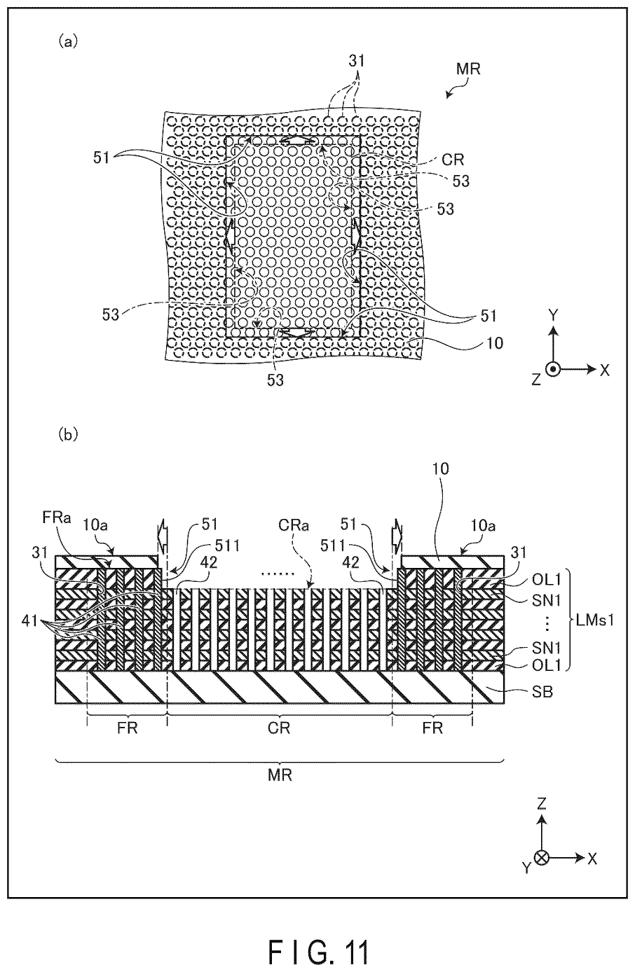

Specifically, as illustrated in FIG. 11, the insulating layer OL1 and the insulating layer 10 included in the side surface 531 of the step 53 are removed by a predetermined thickness using a processing liquid capable of dissolving the insulating layer OL1 and the insulating layer 10, and the side surface 511 is formed. That is, the side surface 511 is a surface obtained by setting back the side surface 531 toward the filler region FR. This exposes a part of the memory hole 31 disposed in the filler region FR on the side surface 511. It is to be noted that the upper surface 10a of the insulating layer 10 is then also removed by a predetermined thickness along with the removal of the insulating layer OL1 and the insulating layer 10 by a predetermined thickness.

Subsequently, a stacked body LMs2 is formed on the stacked body LMs1 (S106 in FIG. 4). The stacked body LMs2 is an example of the second stacked body.

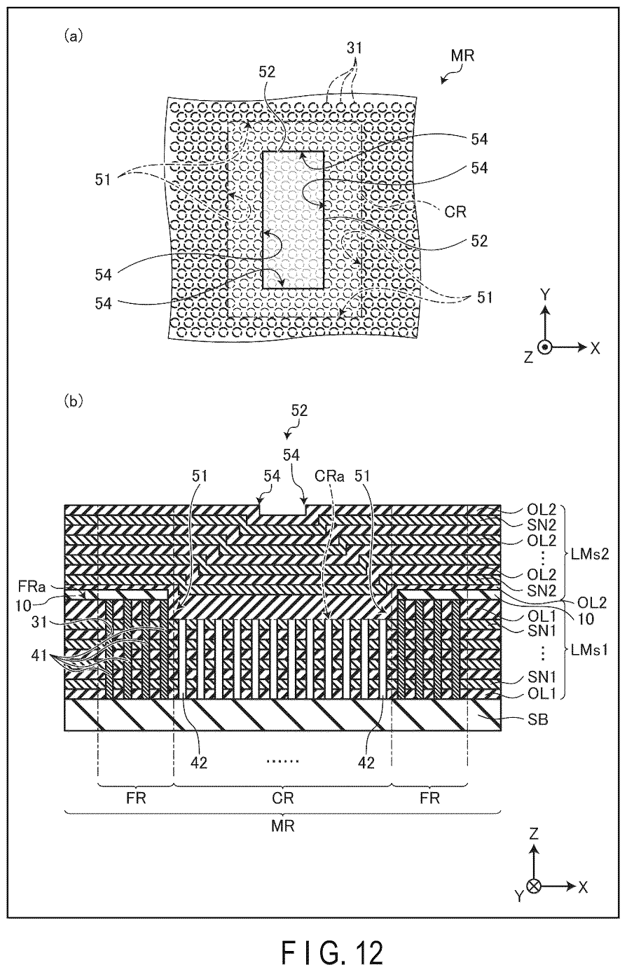

Specifically, as illustrated in FIG. 12, the insulating layer 10 and the stacked body LMs2 are formed on the upper surface 10a of the insulating layer 10 in the filler region FR, the side surface 511 of the step 51, and the upper surface CRa of the cavity region CR. The stacked body LMs2 is formed by alternately stacking the plurality of insulating layers OL2 and a plurality of sacrificial layers SN2 one by one. The sacrificial layers SN2 are, for example, silicon nitride layers. The sacrificial layers SN2 are layers that are each replaced with the electrically conductive layer WL2 in a subsequent process.

The insulating layer 10 and the respective layers of the stacked body LMs2 are formed on the respective portions of the upper surface 10a of the insulating layer 10, the side surface 511 of the step 51, and the upper surface CRa of the cavity region CR to each have a predetermined thickness. This sequentially transfers the shape of a part of the memory hole 31 exposed on the side surface 511 of the step 51 to the insulating layer 10 and the respective layers of the stacked body LMs2 to form the step region 54 on an upper surface LMs2a of the stacked body LMs2. The step 54 is a part of the step region 52. In addition, the step 54 is an example of a second step.

Subsequently, the plurality of memory holes 22 is formed in the stacked body LMs2 in the device region DR using the mark M (see the part (b) of FIG. 1) including the step region 52 formed in this way. Subsequently, the pillar layers 23 (see FIG. 2) are formed inside the memory holes 21 and the memory holes 22 and the sacrificial layers SN1 and SN2 in the stacked bodies LMs1 and LMs2 are replaced with metal layers such as tungsten layers in a predetermined method. This forms the electrically conductive layers WL1 at the portions at which the sacrificial layers SN1 used to be formed and forms the electrically conductive layers WL2 at the portions at which the sacrificial layers SN2 used to be formed, and forms the stacked bodies LM1 and LM2 (see FIG. 2).

The manufacture of the semiconductor storage device 1 thus comes to an end.

### Overview

As an example of a technology compared with the embodiment described above, a method of defining positional information about memory holes formed in a lower stacked body as the presence or absence of the memory holes has been known. In this method, a plurality of memory holes is formed in the lower stacked body along the shapes of marks. The memory holes located at the edge of the region in which the plurality of memory holes is formed are then exposed at a step.

It is, however, more difficult to form memory holes as designed as the memory holes have finer dimensions. In particular, the memory holes located at the edge of the region in which the plurality of memory holes is formed are difficult to process from the perspectives of lithography and etching. For example, this results in opening failure, ununiform dimensions, or the like in many cases. It is not therefore possible to accurately define positional information about the memory holes in some cases.

Meanwhile, in the semiconductor storage device 1 according to the embodiment, the plurality of memory holes 31 is formed in the mark regions MR and each of the regions in which the plurality of memory holes 31 is formed is provided with the filler region FR in which the memory holes 31 the inside of which is filled are disposed and the cavity region CR in which the memory holes 31 inside which the cavities 42 are formed are disposed. The step region 52 is formed in the portion of the upper stacked body LM2 overlaid on the cavity region CR.

This makes it possible to define positional information about the memory holes 31 using the border between the filler region FR and the cavity region CR. It is therefore possible to prevent the accuracy of the positional information about the memory holes 31 from being lower, for example, because of opening failure, ununiform dimensions, or the like. As a result, it is possible to increase the positional accuracy of the step region 52 and it is thus possible to increase the overlay accuracy of the memory holes 21 and 22 in the device region DR.

In addition, in the semiconductor storage device 1 according to the embodiment, a part of the memory hole 31 disposed closer to the filler region FR is exposed on the side surface 511 of the step 51. The most of the memory hole 31 is covered with the insulating layers OL1 or the like of the stacked body LM1. It is therefore possible to prevent the memory hole 31 from, for example, collapsing. As a result, it is possible to further increase the overlay accuracy of the memory holes 21 and 22.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor storage device, comprising:
a device region including a plurality of memory cells; and
a mark region surrounding the device region, wherein
a first stacked body, in which a plurality of first electrically conductive layers is stacked and spaced apart from each other, and a second stacked body, in which a plurality of second electrically conductive layers is stacked and spaced apart from each other, are in the device region and the mark region, the second stacked body being above the first stacked body,
a plurality of first patterns each extending in a stack direction of the first stacked body is in the first stacked body in the device region, the plurality of first patterns constituting the plurality of memory cells,
a plurality of second patterns, each having a dimension identical to a dimension of each first pattern of the plurality of first patterns and extending in the stack direction is in the first stacked body in the mark region,
a region in which the plurality of second patterns is formed includes a first region and a second region, the second region being surrounded by the first region,
the plurality of second patterns in the first region includes filled second patterns,
the plurality of second patterns in the second region second region includes unfilled second patterns, and
a portion of the second stacked body overlying the second region in the mark region includes at least one step region, and the at least one step region is lower than a surface of a portion of the second stacked body that overlies the first region.

2. The semiconductor storage device of claim 1, wherein:
a step down from the first region to the second region is at a border portion between the first region and the second region in the first stacked body, and
at least a part of one second pattern of the plurality of second patterns in the first region is exposed on a side surface of the step facing the second region.

3. The semiconductor storage device of claim 1, wherein the second stacked body does not transmit visible light.

4. The semiconductor storage device of claim 1, wherein an area of the second region of the first stacked body is larger than an area of the at least one step region of the second stacked body.

5. The semiconductor storage device of claim 1, wherein:
the plurality of first patterns and the plurality of second patterns are hole patterns, and
dimensions and pitches of the plurality of first patterns and the plurality of second patterns are both less than or equal to a wavelength of visible light.

6. The semiconductor storage device of claim 1, wherein:
the at least one step region includes a plurality of step regions, and
the plurality of step regions is side by side in the mark region along a transverse direction of the plurality of step regions.

7. The semiconductor storage device of claim 1, wherein the second pattern in the first region is filled with a layer containing carbon.

8. A method for manufacturing a semiconductor storage device, the method comprising:
forming a first stacked body including a device region and a mark region surrounding the device region;
forming a plurality of first patterns in the device region of the first stacked body such that the plurality of first patterns extend in a stack direction of the first stacked body;
forming a plurality of second patterns in the mark region of the first stacked body such that the plurality of second patterns each have a dimension identical to a dimension of each first pattern of the plurality of first patterns and the plurality of second patterns extend in the stack direction of the first stacked body;
forming sacrificial layers inside the plurality of second patterns in the mark region;
forming a mask pattern that covers a first region of the plurality of second patterns and exposes a second region of the plurality of second patterns such that the second region is surrounded by the first region;
removing the sacrificial layers from the second patterns in the second region using the mask pattern and forming a first step down from the first region to the second region at a border portion between the first region and the second region;
exposing at least a part of the sacrificial layer of one second pattern of the plurality of second patterns in the first region on a side surface of the first step facing the second region by setting back the side surface toward the first region; and
forming a second step, transferred from the sacrificial layer of the second pattern exposed on the side surface of the first step, in a portion of a second stacked body overlying the second region by forming the second stacked body on the first stacked body.
